(19) United States
(12) Patent Application Publication
(10) Pub. No.: US 2026/0298401 A1
(43) Pub. Date: Oct. 1, 2026

(54) Low-tension optical bench with thermal decoupling

(71) Applicant: FERDINAND-BRAUN-INSTITUT GGMBH, LEIBNIZ-IBSTITUT FÜR HÖCHSTFREQUENZTECHNIK, Berlin (DE)

(72) Inventors: Dian ZOU, Leipzig (DE); Max SCHIEMANGK, Berlin (DE); Christoph TYBORSKI, Berlin (DE); Sriam HARIHARAN, Köln (DE); Norbert MÜLLER, Woltersdorf (DE); Andreas WICHT, Berlin (DE)

(21) Appl. No.: 19/480,180

(22) PCT Filed: Apr. 26, 2024
(86) PCT No.: PCT/EP2024/061669

§ 371 Date: Oct. 30, 2025

(30) Foreign Application Priority Data
May 4, 2023 (DE) 10 2023 111 589.8

(51) Int. Cl. F16M 11/22; H01S 3/04; H10N 10/13

(52) U.S. Cl. CPC F16M 11/22; H10N 10/13; H01S 3/0405

(57) ABSTRACT

Devices and methods arrange optical components in a thermally decoupled housing that is suspended with low tension, thermally decoupled from a laser housing, and suitable for mobile and satellite-based applications for example in quantum information technology. The devices comprise a housing, an optical bench formed monolithically from a rigid material with high thermal conductivity and yield strength, at least two spring elements, clamping bars beneath the spring elements, thermal insulators beneath the clamping bars, and a thermally conductive strip, wherein a first end of a thermally conductive strip is fastened in a self-supporting region of the optical bench and a second end of the thermally conductive strip is fastened between a pedestal element and a clamping bar next to the thermal insulator.

The present invention relates to a device for arranging optical components in a thermally decoupled housing, in particular an optical bench (OB) which is suspended in a low-tension manner, is thermally decoupled from a laser housing and is suitable for mobile and satellite-based applications, for example in quantum information technology and quantum sensors.

### PRIOR ART

Laser modules that can achieve and provide an ultra-stable frequency reference having low linewidth are required for a large number of applications, including in quantum information technology, in quantum sensors, in optical clocks and for coherent satellite communication. For the operation of laser modules outside of optical laboratories, such as in field operation for applications in quantum computing and in particular for use on a satellite platform, the laser modules have to fulfil particularly high technical requirements. Among other things, the laser modules must:
be small, light and compact,
have a high intrinsic mechanical stability, in particular during the launch for a space mission,
allow temperature control of the opto-mechanical structure, and
be able to ensure a very high thermal stability of the entire opto-mechanical structure during operation.

Since, in the prior art, there have not previously been any suitable laser modules that are able to simultaneously satisfy all of these technical requirements, a low-tension (micro)-optical bench is required, which is thermally decoupled from a housing but is coupled to a dynamically controllable environment for the purpose of temperature stabilization.

In the prior art, temperature-stabilized housing solutions for particularly compact (diode) laser modules are typically configured as butterfly housings (for example, see Lyakh, Arkadiy, et al. “1.6 W high wall plug efficiency, continuous-wave room temperature quantum cascade laser emitting at 4.6 μm.” Applied Physics Letters 92.11 (2008): 111110.). These housings generally use a thermo-electric cooler (TEC; also referred to as a Peltier element) which is located within the laser housing and primarily supports the laser chip and associated collimation optics. The TEC generally has an upper ceramic substrate which can be considered to be an optical bench (OB) and acts as a support for all active and passive optical components of the laser structure. However, the footprint of the OB is limited to the maximum footprint of the used TEC, which is upwardly limited due to technical limitations. In the prior art, a lens is typically used to collimate the output facet of the laser chip; however, but said lens typically is not fastened to the upper ceramic substrate of the TEC and therefore is also not considered to be part of the OB and the temperature stabilization.

A drawback of butterfly housings of this kind is their size limitation. The footprint (length x width) of the OB is limited to the maximum size of the used TEC. As the footprint of the TEC, typically only approximately 20×20 mm² to 25×25 mm² is available in such assemblies in order to avoid damage during the assembly and operation due to thermo-mechanical expansion of the upper ceramic substrate (generally referred to as cold) in relation to the lower ceramic substrate (generally referred to as hot) and of the lower (hot) ceramic substrate in relation to the housing. Furthermore, it should be noted that, if the housing is deformed by external forces, this will have a direct effect on the OB, potentially resulting in a misalignment of the optical components.

DE 10 2022 101 921 A1 relates to a holding assembly having a support platform to which at least one optical element is fixed, the holding assembly being intended to ensure improved beam position stability with the least possible complexity. U.S. Pat. No. 6,771,437 B1 discloses optical bench assemblies and heat management techniques intended to allow increased stability. CN 1 15 799 973 A discloses a packaging structure for heat dissipation for a semiconductor laser.

A further temperature-stabilized housing solution for compact satellite-compatible (diode) laser modules is disclosed in Kürbis et al. (Kürbis, Ch. et al. “Extended cavity diode laser master-oscillator-power-amplifier for operation of an iodine frequency reference on a sounding rocket.” Applied Optics 59.2 (2020): 253-262.) (see FIG. 1), for example. It is known that the OB of a satellite-compatible laser module should be mechanically robust and have as low a thermal expansion coefficient as possible. In order to avoid a thermo-mechanically caused optical misalignment, precise temperature stabilization is also achieved by means of a TEC in satellite-compatible laser systems.

In the laser structure shown in FIG. 1, the OB is made of aluminum nitride for the purpose of mechanical stabilization and is bonded to a laser housing (LH) made of Kovar® by using a thermally conductive adhesive (TCA). The OB is thus rigidly connected to the LH. All electrical and optical components and the diode laser chip are integrated on the top side of the ceramic body of the OB. The LH is screwed to a mounting plate (MP) which also acts as a cooling element. The distance between the LH and the MP is determined by a module spacer (MS), which is used for both mechanical positioning (of the LH on the MP) and thermal isolation (between the LH and the MP). A TEC is located between the LH and the MP (centrally below the LH) and thus is located outside of the LH. In order to improve thermal conductivity, thermally conductive and flexible thermal interface material (TIM) can be located between the LH and the TEC and between the TEC and the MP. The TEC is used for precise temperature control of the OB; for example, the TEC allows heat to be dissipated and the temperature of the OB to be stabilized if the temperature of the LH or the thermal load of the OB changes.

The footprint of the OB of a laser module of this kind can be significantly larger than in the case of a butterfly housing; for example, the OB shown in FIG. 1 has a footprint of typically around 30×80mm² . With other laser modules of this type, OBs having an area of around 60×95 mm² were also achieved. However, with this kind of housing solution, there is a direct effect on the OB if the LH is mechanically deformed by external forces. This can lead to a misalignment of the optical components. Furthermore, a change in temperature of the LH will also have a direct effect on the temperature of OB and cause thermal expansion, which can lead to a shift in the laser frequency. Moreover, if there are significant fluctuations in temperature, relatively large shear stresses occur on the OB if the coefficients of thermal expansion of the LH and OB do not match one another. Therefore, the OB can be expanded and bent, which in turn can lead to optical misalignment. Lastly, the temperature control of the OB by the TEC below the LH requires the stabilization of a non-negligeable overall thermal mass as a result of the material volume of the LH. Furthermore, the TEC offers only a small control bandwidth (slow temperature control) owing to the relatively large thermal resistance of the control loop and the relatively large thermal resistance along the heat flow path via TIM, TCA and LH.

### DISCLOSURE OF THE INVENTION

An object of the present invention is therefore to provide a low-tension optical bench having good thermal coupling to the environment, said optical bench avoiding or at least significantly reducing the drawbacks to the prior art. In particular, a micro-optical bench which is suspended in a low-tension manner and is thermally well decoupled from a housing is to be provided, said bench being suitable for mobile and satellite-based applications, for example in quantum information technology and quantum sensors.

These objects are achieved according to the invention by the features of the independent claim. Advantageous embodiments of the invention are contained in the associated dependent claims. The features set out individually in the claims can be combined with one another where this is technically feasible. Moreover, explanatory matters from the description and/or details from the figures can be added to these features, with further embodiment variants of the invention being revealed.

A device according to the invention for arranging optical components in a housing has: a housing; an optical bench which is formed in one piece from a rigid material having a high thermal conductivity and yield strength; at least two spring elements at the outer edges of the optical bench, said spring elements acting in the plane of the optical bench, wherein the optical bench is fastened to pedestal elements of the housing exclusively by means of the spring elements, and the optical bench is self-supportingly held in the housing by means of the pedestal elements; clamping bars below the spring elements; thermal isolators below the clamping bars, wherein the clamping bars rest at least in portions on the thermal isolators, and the clamping bars are stably supported thereby in relation to the pedestal elements of the housing; and a thermal strap, wherein a first end of the thermal strap is fixed to a self-supporting region of the optical bench, and a second end of the thermal strap is fixed between a pedestal element and a clamping bar next to a thermal isolator.

In particular, the housing can be a laser housing for accommodating a (diode) laser assembly on the optical bench. However, the present invention is not limited to such applications and can also relate, for example, to a detector housing for accommodating a detector assembly on the optical bench. The house can be made of stainless steel, Kovar or aluminum, for example.

The material of the optical bench is intended to be rigid, i.e. to have as high as possible a modulus of elasticity E. Preferably, the material has a modulus of elasticity E of more than 70 GPa, preferably more than 100 GPa, more preferably more than 200 GPa. The thermal conductivity x should also be as high as possible; preferred are values of more than 75 W/(m. K), more preferably more than 150 W/(m. K), even more preferably more than 200 W/(m. K). The yield strength Re refers to the mechanical tension up to which a material can be elastically deformed. Thus, this value should also be as high as possible. Typically, with technical materials, the 0.2% proof stress (also referred to as the elastic limit R_{p0.2}), which can be determined more accurately, is indicated instead of the yield strength. Preferred values for the 0.2% proof stress are more than 200 MPa, preferably more than 300 MPa, more preferably more than 500 MPa. A particularly high yield strength (or 0.2% proof stress) is preferred since the material of the optical bench can be used for mechanically decoupling the optical bench from the surroundings and plastic deformation must absolutely be avoided when there is mechanical stress. Preferably, the optical bench is a micro-optical bench. In the context of this application, micro-optical benches are understood to be optical benches having a maximum area of up to around 10,000 mm² (e.g. an optical bench having an area of 60×95 mm² ). However, the present invention is not limited to micro-optical benches of this kind.

The spring elements at the outer edges of the optical bench are in particular intended to act in the plane of the optical bench. As a result, different expansions of the optical bench and the housing can be compensated for. However, in addition, the spring elements can also have a spring component acting perpendicular to the plane of the optical bench. In addition to said expansion compensation, this also allows compensation for any bending between the housing and the optical bench. The spring elements can thus be designed to act in different directions.

The pedestal elements of the housing have the purpose of allowing resting and supporting points for a self-supporting hold of the optical bench. The pedestal elements should have a sufficient height in relation to a housing base in order to keep both the optical bench and the thermal straps, preferably located on the bottom side, away from the base of the housing.

The invention solves the technical problem of mounting the optical bench in the housing, specifically such that the mechanical and thermomechanical stress and the deformation are kept away from the optical bench, simultaneously allowing good thermal decoupling of the optical bench from the housing.

In particular, the optical bench can also be decoupled from mechanical stress from the surroundings. Mechanical stress that may occur as a result of mechanical deformation of the laser housing or as a result of relative thermal expansion or contraction of the optical bench and/or the housing is not transferred to the optical bench since the flexible solid structures that are subject to mechanical stress can absorb all stress and deformation occurring as a result of the change in the surroundings. As a result, the material of the housing may also be different from the material of the optical bench.

Preferably, the spring elements are solid-state joint structures arranged in one plane together with the optical bench. The spring elements can thus be designed to act in different directions. Preferably, the solid-state joint structures can act in the plane of the optical bench and perpendicular to said plane. The spring elements can comprise narrow connecting pieces and tapered regions, by means of which the self-supporting optical bench and the portions of the individual spring elements rigidly connected to the pedestal elements of the housing can be largely mechanically decoupled from one another. In particular, by means of the spring elements, tension occurring between the housing and the optical bench can be absorbed such that said tension cannot affect the optical bench.

Preferably, the spring elements are formed in one piece from the material of the optical bench. This allows a uniform formation of the structures and increases the reliability thereof. Alternatively, however, the spring elements can also be formed independently of the optical bench, from the same material as the optical bench or a material different from the optical bench, and can be connected to said optical bench. The connection can be established by soldering, welding, bonding, screwing or a combination thereof.

Preferably, the optical bench is made of a Mo₇₀Cu₃₀ alloy, Kovar or another metal or ceramic material. The use of MO₇₀Cu₃₀ alloy is particularly preferred since the material MO₇₀Cu₃₀ has the properties of not being magnetic, has a low gas content, provides a high thermal conductivity and a low coefficient of thermal expansion, is suitable for vacuum applications and is easy to work. Furthermore, said material has a coefficient of thermal expansion that largely matches that of GaAs (a material typically used for laser chips). A MO₇₀Cu₃₀ alloy for forming an optical bench is previously unknown in the prior art. However, instead of a particularly preferred MO₇₀Cu₃₀ alloy, it is also possible to use a different MoₓCu₁₀₀₋ₓ alloy where x is between 50 and 90, preferably between 60 and 80. A suitable ceramic material can be aluminum oxide or aluminum nitride, for example.

Preferably, the optical bench is connected to the pedestal elements in the housing by means of a screw connection, a soldered connection, a welded connection, a clamping connection, a bonded connection or a combination thereof. In addition to simple release of the connection, a screw connection offers the advantage of distinctive reliability and simplicity.

Preferably, the first end of the thermal strap is fastened to the optical bench by means of a soldered connection, a welded connection, an adhesive connection or a clamping connection. In order to improve thermal transmission, a thermal interface material can be placed between the first end of the thermal strap and the optical bench.

Preferably, a thermo-electric cooler is located between the second end of the thermal strap and the pedestal element. Alternatively or additionally, a resistance heater is also located between the second end of the thermal strap and the pedestal element. In particularly cold environments (Arctic, space), the resistance heater can additionally be used, in addition to the thermo-electric cooler, to heat the optical bench and can thus provide a “thermal offset” for providing base heat, even without fast control by means of a thermo-electric cooler. If, however, fast temperature control is not required, the resistance heaters can also be used without additional thermo-electric coolers.

Preferably, a thermo-electric cooler or resistance heater located between the second end of the thermal strap and the pedestal element contacts the second end of the thermal strap on the top and/or bottom side thereof either directly or via a thermal interface material. In this case, the fixing can be established by soldering, welding, bonding, screwing or a combination thereof, for example.

An optical bench according to the invention offers significant advantages over the solutions known in the prior art. The optical bench according to the invention can be fixed to the housing by means of screws. The optical bench can support optical components such as lenses, mirrors, polarization optics (retardation plates, polarizers), electro-optical or acoustic-optical modulators, laser chips, gas cells and/or discrete electronics (temperature sensors, TECs, photodiodes and the like) in order to function as a laser, a spectroscopy device, a module for beam switching, beam distribution or beam merging for generating laser pulses, or a combination thereof.

The spring elements can be provided by cutting out certain portions of a material for providing the optical bench in order to provide flexible stress-resistant mechanical structures (including bends, tapered portions and articulations).

The thermo-electric coolers or resistance heaters, the thermal interface material and the thermal isolators can be accommodated entirely within the housing and can be located between the optical bench and the housing. Therefore, the heating or cooling of the optical bench can be controlled by the operation of the thermo-electric coolers and/or the resistance heaters, and the optical bench and the housing are thermically decoupled from one another. A change in temperature of the housing therefore does not affect the temperature of the optical bench since the optical bench since the thermo-electric coolers or resistance heaters, the thermal interface material and the thermal isolators between the optical bench and the laser housing make it possible to control the temperature of the optical bench, independently of the temperature of the housing.

Flexible thermal straps can connect the bottom side of the optical bench to the thermo-electric coolers and/or resistance heaters in order provide specific paths for heat transfer. The thermal straps can be bonded to the optical bench at one end by means of a thermally conductive adhesive and can be fastened to the thermo-electric coolers and/or resistance heaters at the other end. The thermal straps allow thermal contact between the optical bench and the thermo-electric coolers or resistance heaters, without establishing a strong mechanical coupling between the optical bench and the thermo-electric coolers or resistance heaters. In comparison with the prior art, the thermo-electric coolers and/or resistance heaters can be located significantly closer to the optical bench, as a result of which the thermal resistance between the housing and the optical bench is smaller and improved and accelerated temperature control of the optical bench are made possible.

In addition, in comparison with devices according to the prior art, the present invention is significantly more robust with respect to vibrations, mechanical deformation and stress and with respect to temperature fluctuations since the optical bench is not rigidly connected to the housing, owing to the spring elements, and is thermally decoupled from the housing, owing to the specific configuration of the heat pathways.

In certain exemplary embodiments of the present invention, the spring elements in particular can be configured so as not to be flexible in all directions, and the arrangement and properties thereof are selected such that the optical bench adopts a defined position. The optical bench is intended not to be mounted by means of the spring elements so as “float” freely in the housing; instead, the spring elements are intended merely to conform to deformations of the housing by adapting accordingly and can absorb the occurring mechanical forces and stress, without also deforming the optical bench as a result.

The present invention can be used, for example, as:
an ultra-stable clock laser in an optical atomic clock system,
a local oscillator for coherent (inter-)satellite communication,
a laser system for neutral atom-based or ion-based quantum calculations, and
a laser system for atom-interferometry inertial navigation or for gravity gradiometry.

The present invention can further be used to implement photonic modules and systems that allow laser beam control, e.g., for pulse generation, beam combination and distribution and the like. In general, the present invention aids the miniaturization of both photonic and electro-optical solutions.

Further preferred embodiments of the invention follow from the features set out in the dependent claims.

The different embodiments of the invention set out in this application are advantageously able to be combined with one another unless otherwise specified.

### BRIEF DESCRIPTION OF THE DRAWINGS

The invention and the technical context are described in more detail below with reference to the accompanying drawings. It should be noted that the invention is not intended to be limited by the exemplary embodiments indicated. In particular, unless explicitly stated otherwise, it is also possible to extract certain aspects of the matters described in the drawings and to combine the same with other parts and findings from the present description. In the drawings:

FIG. 1 is a schematic view of a device for arranging optical components according to the prior art;

FIG. 2 is a schematic view of an embodiment of a device according to the invention for arranging optical components; and

FIG. 3 is a schematic view of the device according to the invention for arranging optical components according to FIG. 2 in cross section.

### DETAILED DESCRIPTION OF THE DRAWINGS

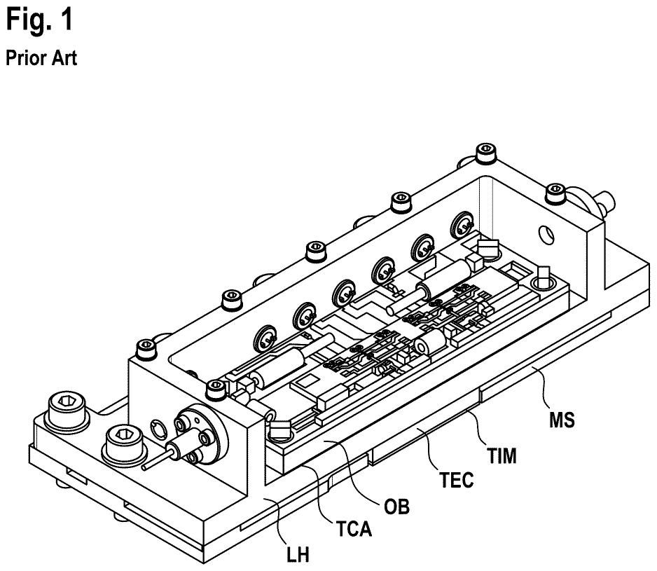

FIG. 1 is a schematic view of a device for arranging optical components according to the prior art. The disclosed device is a housing for compact satellite-compatible (diode) laser modules according to Kürbis et al. (Kürbis, Ch. et al. “Extended cavity diode laser master-oscillator-power-amplifier for operation of an iodine frequency reference on a sounding rocket.” Applied Optics 59.2 (2020): 253-262.), in which, for the purposes of mechanical stability, the optical bench OB is made of aluminum nitride and is bonded to a housing LH made of Kovar by using a thermally conductive adhesive TCA. The optical bench OB is thus rigidly connected to the LH. All the electrical and optical components and the diode laser chip are integrated on the top side of the ceramic body of the optical bench OB.

The housing LH is screwed to a mounting plate (MP) (not shown), which also acts as a cooling element. The distance between the housing LH and the mounting MP is determined by a module spacer (MS), which is used for both mechanical positioning (of the housing LH on the mounting plate MP) and thermal isolation (between the housing LH and the mounting plate MP). A thermo-electric cooler (Peltier element) TEC is located between the housing LH and the mounting plate MP (centrally below the housing LH) and thus is located outside of the housing LH. In order to improve thermal conductivity, thermally conductive and flexible thermal interface material (TIM) can be located between the housing LH and the thermo-electric cooler TEC and between the thermo-electric cooler TEC and the mounting plate MP. The thermo-electric cooler TEC is used for precise temperature control of the optical bench OB; for example, the thermo-electric cooler TEC allows heat to be dissipated and the temperature of the optical bench OB to be stabilized if the temperature of the housing LH or the thermal load of the optical bench OB changes.

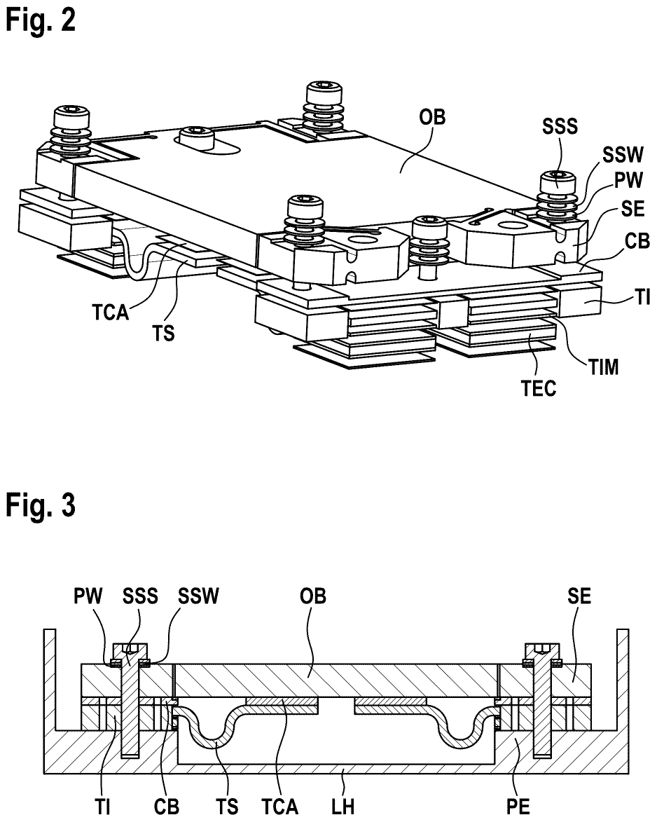

FIG. 2 is a schematic view of an embodiment of a device according to the invention for arranging optical components. The device has: a housing LH (not shown); an optical bench OB which is formed in one piece from a rigid material having a high thermal conductivity and yield strength; at least two spring elements SE at the outer edges of the optical bench OB, said spring elements acting in the plane of the optical bench OB (i.e. against the outer edges), wherein the optical bench OB is fastened to pedestal elements PE of the housing LH exclusively by means of the spring elements SE, and the optical bench OB is self-supportingly held in the housing LH by means of the pedestal elements PE; clamping bars CB below the spring elements SE; thermal isolators TI below the clamping bars CB, wherein the clamping bars CB rest at least in portions on the thermal isolators TI, and the clamping bars CB can be stably supported thereby in relation to the pedestal elements PE of the housing LH; and a thermal strap TS, wherein a first end of the thermal strap TS is fixed to a self-supporting region of the optical bench OB, and a second end of the thermal strap TS is fixed between a pedestal element PE and a clamping bar CB next to a thermal isolator TI.

In particular, the housing LH can be a laser housing for accommodating a (diode) laser assembly on the optical bench OB. However, the present invention is not limited to such applications and can also relate, for example, to a detector housing for accommodating a detector assembly on the optical bench OB.

The spring elements SE are solid-state joint structures arranged in one plane together with the optical bench OB. The solid-state joint structures elements can be configured to act in different directions. Preferably, the solid-state joint structures can act in the plane of the optical bench OB and perpendicular to said plane. In addition, as shown, the spring elements SE can comprise narrow connecting pieces (acting in the plane of the optical bench OB) and tapered regions (acting perpendicular to the plane of the optical bench OB), by means of which the self-supporting optical bench OB and the portions of the individual spring elements SE rigidly connected to the pedestal elements PE of the housing LH are largely mechanically decoupled from one another. In particular, by means of the spring elements SE, tension occurring as a result of different expansion or bending between the housing LH and the optical bench OB can be absorbed such that said tension cannot affect the optical bench OB. However, the present invention is not limited to the solid-state joint structures shown in the figure only by way of example.

In the figure, the spring elements SE are formed in one piece from the material of the optical bench OB. However, the spring elements SE can also be formed independently of the optical bench OB, from the same material as the optical bench OB or a material different from the optical bench OB, and can be connected to said optical bench OB. The optical bench OB is preferably made of a MO₇₀Cu₃₀ alloy, Kovar or another metal or ceramic material.

The optical bench OB shown is connected to the pedestal elements PE in the housing LH by means of a screw connection. Alternatively, however, a soldered connection, a welded connection, a clamping connection, a bonded connection or a combination thereof can also be used, for example. The first end of the thermal strap TS on the optical bench OB is preferably fastened by means of a soldered connection, a bonded connection, a welded connection or a clamping connection.

A thermo-electric cooler (Peltier element) TEC is located between the second end of the thermal strap TS and the pedestal element PE. Instead of the thermo-electric cooler TEC or in addition thereto, a resistance heater is also located between the second end of the thermal strap TS and the pedestal element PE. A thermo-electric cooler TEC or resistance heater located between the second end of the thermal strap TS and the pedestal element PE can contact the second end of the thermal strap TS on the top and/or bottom side thereof either directly or via a thermal interface material TIM.

In particular, the device shown has six stainless-steel screws SSS for fastening in a housing LH to two pedestal elements PE (the housing is not shown in the figure), twelve stainless-steel washers SSW, six PEEK washers PW made of polyetheretherketone (PEEK), an optical bench OB, four spring elements SE, two clamping bars CB (one clamping bar CB as a support for each of two adjacent spring elements SE), six thermal isolators TI made of polyetheretherketone (PEEK), thermally conductive adhesive TCA, four thermal straps TS, thermal interface material TIM and four thermo-electric coolers TEC. The assembly of a such a preferred embodiment, given by way of example, comprises a combination of bonding, pressing and screwing between the optical bench OB and the laser housing LH.

The optical bench OB preferably is made of a material which is novel for this purpose and which consists of (pure) molybdenum and an (oxygen-free) copper alloy (MO₇₀Cu₃₀). Alternatively, a ceramic material such as aluminum nitride or a different metal material such as Kovar can be used to produce the optical bench OB. However, the ceramic material (aluminum nitride) used in Kürbis et al. is not suitable for the described embodiment of the present invention with screw connections since it is not suitable for screwing due to its rigidity. A MO₇₀Cu₃₀ alloy for forming an optical bench is previously unknown in the prior art. However, instead of a particularly preferred Mo₇₀Cu₃₀ alloy, it is also possible to use a different MoₓCu₁₀₀₋ₓ alloy where x is between 50 and 90, preferably between 60 and 80.

In the embodiment shown, four spring elements SE which act in the plane of the optical bench OB (i.e. against the outer edges) and perpendicular thereto (i.e. with respect to an upward or downward bend) are arranged at the corners of the rectangular optical bench OB at the outer edges of the optical bench OB. The four spring elements SE each include a screw hole. In the screw holes, there are four stainless-steel screws SSS, by means of which the optical bench OB can be rigidly connected to a pedestal element PE of the housing LH. In the process, however, the optical bench OB is not directly fastened to the pedestal elements PE of the housing LH but is fastened via two clamping bars CB (arranged in parallel at two opposite edges of the optical bench) and four thermal isolators TI arranged underneath. The clamping bars CB, which can also be made of MO₇₀Cu₃₀ or another alloy corresponding to the material of the optical bench OB, are used to clamp all thermo-mechanical components, such as the thermal isolators TI, the thermal straps TS, the thermal interface material TIM and the thermo-electric coolers TEC. Each clamping bar CB and each thermal isolator TI contain suitably positioned screw holes in order to allow the screw connection between a spring element SE and the associated pedestal element PE of the housing LH.

The middle portion of the optical bench OB on which the optical components are arranged is suspended inside the housing LH on mechanical solid-state joint structures and does not make contact with the base of the housing LH. The solid-state joint structures are aligned and positioned so as to be able to ensure isostatic mounting of the optical bench OB in relation to the housing LH. The disclosed flexible solid-state joint structures that absorb mechanical stress are able to ensure isostatic mounting in particular when the hinges are freely rotatable, can bend/deform freely in the intended direction and are virtually permanently rigid with respect to any other deformation. By means of this isostatic or virtually isostatic mounting, the deformation of the optical bench OB, which results from mechanical deformation of the housing LH or deformation owing to a thermally caused expansion or contraction of the housing LH or of the optical bench OB or both, can be significantly reduced in comparison with previous solutions in the prior art.

The stainless-steel screws SSS (including the stainless-steel washers SSW) are not in direct contact with the surface of the optical bench OB but are thermally decoupled by PEEK washers PW located in between. The PEEK washers are used to reduce direct heat transfer between the housing LH and the optical bench OB along the stainless-steel screws SSS and stainless-steel washers SSW. Moreover, the PEEK washers SSW provide a high level of mechanical strength. As a result of the use of thermal isolators TI, direct flow of heat between the housing LH and the spring elements SE via the fastening regions of the stainless-steel screws SSS is avoided, while a vertical space for the middle portion of the optical bench OB is provided in order to prevent contact with the base of the housing LH.

Four thermal straps TS are mounted below the optical bench OB. A first end of each of the thermal straps TS can be fastened to a central, lower portion of the optical bench OB by means of a thermally conductive adhesive TCA. The second end can also be fastened to a clamping bar CB by means of a thermally conductive adhesive TCA.

Four thermo-electric coolers TEC are mounted below the second ends of the thermal straps TS and are connected thereto by means of optionally interposed thermal interface material TIM on the top side of the TECs. The bottom side of the thermo-electric coolers TEC is connected to the base of the housing LH or to the pedestal elements PE located therein, it also being possible for a connection to be established via optionally interposed thermal interface material TIM. The thermal straps TS are used to define the path for the heat transfer from the optical bench OB to the thermo-electric coolers TEC; a thermal short circuit between the edges of the optical bench OB supported by the spring elements SE and the corresponding corners of the housing LH is avoided or suppressed by means of the thermal isolators TI. The thermal interface material TIM is preferably used to ensure good thermal conductivity between the thermo-electric coolers TEC and the housing LH and between the thermo-electric coolers TEC and the thermal straps TS.

An additional combination of a module spacer MS and a mounting plate MP as in the prior art is not required since the thermo-electric coolers TEC in the shown embodiment of the invention are arranged within the housing LH. The clamping bars CB uniformly distribute the forces introduced by the stainless-steel screws onto the assembly consisting of the thermo-electric coolers TEC, the thermal straps TS and the thermal interface material TIM and fix these components relative to one another in the installation space of the housing LH.

Furthermore, as illustrated in the figure, above additional screw holes in the clamping bars CB, two additional sets of stainless-steel screws SSS and stainless-steel washers SSW, PEEK washers PW and thermal isolators are used in the center of the two clamping bars CB. Thus, non-uniform compression of the clamping bars on the components located underneath is avoided, which can lead to bending and a large horizontal shift (in the case of shock and vibration) of the TECs, thermal straps TS and thermal isolators TIM.

FIG. 3 is a schematic view of an embodiment of a device according to the invention for arranging optical components according to FIG. 2 in cross section. The individual reference signs and the features associated therewith apply accordingly. The same reference signs belong to the same features. It is therefore not necessary to provide a detailed description of the individual features shown. Reference is made to FIG. 2. Said figure shows both the self-supporting structure of the optical bench OB and the spring elements SE located on the respective pedestal elements PE at the respective outer edges of the optical bench OB. The optical bench OB is thermally coupled to the surroundings and to the housing LH via thermal straps TS.

### LIST OF REFERENCE SIGNS

MS module spacer
MP mounting plate
TIM thermal interface material
TEC thermo-electric cooler/Peltier element
LH laser housing
TCA thermally conductive adhesive
OB optical bench
TS thermal strap
TI thermal isolator
CB clamping bar
SSS stainless-steel screw
SSW stainless-steel washer
PW PEEK washer
PE pedestal element
SE spring element

1. A device for arranging optical components in a housing, comprising:
a housing;
an optical bench formed in one piece from a rigid material having a high thermal conductivity and yield strength;
at least two spring elements at the outer edges of the optical bench, the spring elements acting in the plane of the optical bench, wherein the optical bench is fastened to pedestal elements of the housing exclusively by means of the spring elements, and the optical bench is self-supportingly held in the housing by means of the pedestal elements;
clamping bars below the spring elements;
thermal isolators below the clamping bars, wherein the clamping bars rest at least in portions on the thermal isolators, and the clamping bars can be stably supported thereby relative to the pedestal elements of the housing; and
a thermal strap, wherein a first end of the thermal strap is fixed to a self-supporting region of the optical bench, and a second end of the thermal strap is fixed between a pedestal element and a clamping bar next to a thermal isolator.

2. The device of claim 1, wherein the spring elements are solid-state joint structures arranged in one plane together with the optical bench.

3. The device of claim 1 , wherein the spring elements are formed in one piece in the material of the optical bench.

4. The device of claim, wherein the spring elements are formed independently of the optical bench, from the same material as the optical bench or a material different from the optical bench, and are connected to said optical bench.

5. The device of claim 1, wherein the optical bench is made of a Mo₇₀Cu₃₀ alloy, Kovar or another metal or ceramic material.

6. The device of claim 1, wherein the optical bench is connected to the pedestal elements in the housing by means of a screw connection, a soldered connection, a welded connection or a bonded connection.

7. The device of claim 1, wherein the first end of the thermal strap is fastened to the optical bench by means of a soldered connection, a welded connection, a bonded connection or a clamping connection.

8. The device of claim 1, wherein a thermo-electric cooler is located between the second end of the thermal strap and the pedestal element.

9. The device of claim 1, wherein a resistance heater is located between the second end of the thermal strap and the pedestal element.

10. The device of claim 1, wherein a thermo-electric cooler or resistance heater located between the second end of the thermal strap and the pedestal element contacts the second end of the thermal strap on the top side and/or bottom side thereof either directly or via a thermal interface material.

11. The device according to claim 1, wherein a thermo-electric cooler or resistance heater located between the second end of the thermal strap and the pedestal element contacts the second end of the thermal strap on the top side or bottom side thereof either directly or via a thermal interface material.
